(19) United States
(12) Patent Application Publication
(10) Pub. No.: US 2026/0324185 A1
(43) Pub. Date: Oct. 15, 2026

(54) ELECTRONIC DEVICE AND METHOD OF MANUFACTURING THE SAME

(71) Applicant: Samsung Display Co., Ltd., Yongin-si (KR)

(72) Inventors: JONGJANG PARK, Yongin-si (KR); Dongjin KANG, Yongin-si (KR)

(21) Appl. No.: 19/572,022

(22) Filed: Mar. 19, 2026

(30) Foreign Application Priority Data
Apr. 11, 2025 (KR) 10-2025-0047665

(51) Int. Cl. H10K 50/115; H10K 50/16; H10K 50/844; H10K 71/13; H10K 102/00

(52) U.S. Cl. CPC H10K 50/115; H10K 50/16; H10K 50/844; H10K 71/135; H10K 2102/351

(57) ABSTRACT

Disclosed is an electronic device including a display element layer including a light emitting element and an aging layer on the light emitting element. The light emitting element includes a first electrode, a second electrode on the first electrode, a light emitting layer between the first electrode and the second electrode including a quantum dot, and an electron transport area including a metal oxide between the first electrode and the second electrode, and the aging layer includes a porous film including a polymer, a ceramic, or a combination thereof and a coating film including an organic acid. Accordingly, the electronic device according to one or more embodiments may exhibit excellent or suitable display quality and excellent or suitable reliability.

### CROSS-REFERENCE TO RELATED APPLICATION

The present application claims priority to and the benefit of Korean Patent Application No. 10-2025-0047665 filed on Apr. 11, 2025, in the Korean Intellectual Property Office, the entire disclosure of which is incorporated herein by reference.

### BACKGROUND

### 1. Field

Embodiments of the present disclosure described herein are related to an electronic device including an aging layer including a porous film and a coating film, and a method of manufacturing an electronic device.

### 2. Description of the Related Art

Multimedia electronic devices such as televisions, mobile phones, tablet computers, navigation devices, game consoles, and/or wearable devices may include display modules that display images. In the display module, a so-called self-luminous light-emitting element that implements display by emitting light to a light-emitting material containing organic compounds or quantum dots in a light emitting layer between facing electrodes is used. To improve quality of an electronic device, it is necessary or desirable to improve light efficiency and a lifespan of the light emitting element.

The information disclosed in this Background section is intended to enhance understanding of the background of the disclosure and therefore it may contain information that does not constitute prior art.

### SUMMARY

One or more embodiments of the present disclosure provide an electronic device exhibiting excellent or suitable display quality and excellent or suitable reliability.

One or more embodiments of the present disclosure also provide a method of manufacturing an electronic device having excellent or suitable manufacturing efficiency.

According to one or more embodiments, an electronic device includes a display module that provides an image, wherein the display module includes a display element layer including a light emitting element and an aging layer on the light emitting element, the light emitting element includes a first electrode, a second electrode on the first electrode, a light emitting layer between the first electrode and the second electrode including a quantum dot, and an electron transport area including a metal oxide between the first electrode and the second electrode, and the aging layer includes a porous film including a polymer or a ceramic on the light emitting element and a coating film including an organic acid on the porous film.

A thickness of the porous film may be in a range of 5μm to 100μm.

The polymer may include polydimethylsiloxane, and the ceramic may include a silicon oxy carbide.

The coating film may further include a polymer matrix.

The organic acid may include a methacrylic acid, an acrylic acid, a citric acid, or a combination thereof.

The organic acid may include a carboxyl group.

The aging layer may be directly on the light emitting element.

The display module may further include an encapsulation layer on the aging layer.

The metal oxide may include SnO, SnO₂, CuGaO₂, Ga₂O₃, Cu₂O, SrCu₂O₂, SrTiO₃, CuAlO₂, Ta₂O₅, NiO, BaSnO₃, TiO₂, a compound represented by a following chemical formula M-1, or a combination thereof.
[Chemical formula M-1]
Zn_{(1-q)}Me_{q}O

In the chemical formula M-1, q may be 0 or more and 0.5 or less, and Me may be Li, Be, Na, Mg, Al, K, Ca, Ti, V, Cr, Mn, Fe, Co, Ni, Cu, Ga, Ge, Rb, Sr, Zr, Nb, Mo, Ru, Pd, Ag, In, Sn(II), Sn(IV), Sb, or Ba.

The light emitting element may further include a hole transport area, and one of the hole transport area and the electron transport area may be between the first electrode and the light emitting layer, and the other one thereof may be between the light emitting layer and the second electrode.

The electronic device may further include a processor, a memory, a power module, or a combination thereof.

According to one or more embodiments, a method of manufacturing an electronic device includes preparing a light emitting element, forming an aging layer, and providing the aging layer onto the light emitting element, wherein the forming of the aging layer includes preparing a porous film, providing a resin composition including an organic acid onto the porous film, and forming a coating film by radiating light to the resin composition, the light emitting element includes a first electrode, a second electrode on the first electrode, a light emitting layer between the first electrode and the second electrode including a quantum dot, and an electron transport area including a metal oxide between the first electrode and the second electrode, and the porous film includes a polymer, a ceramic, or a combination thereof.

The method may further include providing an encapsulation layer onto the aging layer after the providing of the aging layer.

The aging layer may be coupled to the light emitting element in a lamination process.

The resin composition may further include a polymer matrix.

The resin composition may be provided by an inkjet printing method or a dispensing method.

### BRIEF DESCRIPTION OF THE DRAWINGS

The above and other aspects and features of the present disclosure will become more readily apparent by describing in more detail embodiments thereof with reference to the accompanying drawings, in which:

FIG. 1 is a block diagram of an electronic device according to one or more embodiments;

FIG. 2 is a view illustrating an electronic device according to one or more embodiments;

FIG. 3 is a perspective view illustrating an electronic device according to one or more embodiments;

FIG. 4 is an exploded perspective view illustrating the electronic device according to one or more embodiments;

FIG. 5 is a cross-sectional view illustrating a portion corresponding to line I-I’ of FIG. 4;

FIG. 6 is a plan view of a portion of the electronic device according to one or more embodiments;

FIG. 7 is a cross-sectional view illustrating a portion corresponding to line II-II' of FIG. 6;

FIG. 8A is a cross-sectional view illustrating a light emitting element according to one or more embodiments;

FIG. 8B is a cross-sectional view illustrating the light emitting element according to one or more embodiments;

FIG. 8C is a cross-sectional view illustrating the light emitting element according to one or more embodiments;

FIG. 8D is a cross-sectional view illustrating the light emitting element according to one or more embodiments;

FIG. 9A is a flowchart illustrating a method of manufacturing an electronic device according to one or more embodiments;

FIG. 9B is a flowchart illustrating the method of manufacturing an electronic device according to one or more embodiments;

FIG. 10A is a schematic view illustrating an operation of manufacturing an electronic device according to one or more embodiments;

FIG. 10B is a schematic view illustrating the operation of manufacturing an electronic device according to one or more embodiments;

FIG. 10C is a schematic view illustrating the operation of manufacturing an electronic device according to one or more embodiments; and

FIG. 10D is a schematic view illustrating the operation of manufacturing an electronic device according to one or more embodiments.

### DETAILED DESCRIPTION

The subject matter of the present disclosure may be implemented to have various suitable modifications and have various suitable forms, and example embodiments are illustrated in the drawings and described in more detail in the text. It is to be understood, however, that the present disclosure is not intended to be limited to the particular forms disclosed, but on the contrary, is intended to cover all modifications, equivalents, and alternatives falling within the spirit and scope of the present disclosure.

In the specification, the expression that a first component (or area, layer, part, portion, etc.) is “on,” “connected with,” or “coupled to” a second component means that the first component is directly arranged/connected with/coupled to the second component or means that a third component is interposed therebetween.

The same reference numerals refer to the same components. Furthermore, in the drawings, the thickness, the ratio, and the dimension of components are exaggerated for effective description of technical contents. The expression “and/or” includes all combinations of one or more of the associated listed components.

Although the terms “first,” “second,” etc., may be used to describe one or more suitable components, the components should not be limited by the terms. The terms are used only to distinguish one component, one part, one area, one layer or one portion from another component, another part, another area, another layer or another portion. For example, without departing from the scope of the present disclosure, a first component, a first part, a first area, a first layer, or a first portion may be referred to as a second component, a second part, a second area, a second layer, or a second portion, and similarly, the second component, the second part, the second area, the second layer, or the second portion may also be referred to as the first component, the first part, the first area, the first layer, or the first portion. Singular expressions include plural expressions unless clearly otherwise indicated in the context.

Also, the terms “under”, “below”, “on”, “above” and the like, may be used to describe the correlation of components illustrated in the drawings. The terms that are relative in concept are described based on a direction illustrated in the drawings.

In the present disclosure, it will be further understood that the terms “include”, "comprise", "have" and the like, specify the presence of features, numbers, steps, operations, elements, or components, described in the specification, or a combination thereof, and do not exclude in advance the presence or additional possibility of one or more other features, numbers, steps, operations, elements, components, or a combination thereof.

Unless otherwise defined, all terms (including technical terms and scientific terms) used in the specification have the same meaning as commonly understood by those skilled in the art to which the present disclosure belongs. Furthermore, terms, such as terms defined in the dictionaries commonly used, should be interpreted as having a meaning consistent with the meaning in the context of the related technology and should not be interpreted in an idealized or overly formal meaning unless explicitly defined herein.

Hereinafter, one or more embodiments of the present disclosure will be described in more detail with reference to the accompanying drawings.

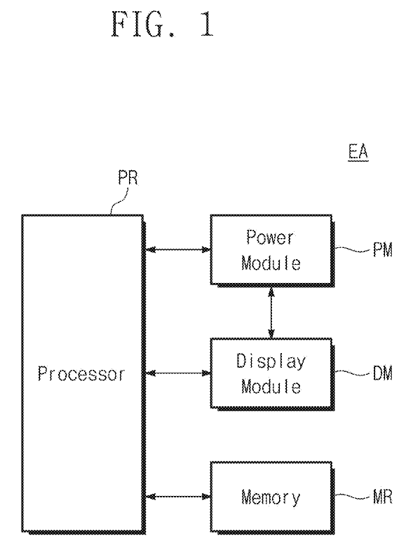

FIG. 1 is a block diagram of an electronic device according to one or more embodiments. An electronic device EA may include a display module DM. The electronic device EA may further include at least one of a processor PR, a memory MR, and a power module PM. Referring to FIG. 1, the electronic device EA according to one or more embodiments may include the display module DM, the processor PR, the memory MR, and the power module PM.

The processor PR may include at least one of a central processing unit (CPU), an application processor (AP), a graphic processing unit (GPU), a communication processor (CP), an image signal processor (ISP), or a controller.

Data information useful or required to operate the processor PR or the display module DM may be stored in the memory MR. If (e.g., when) the processor PR executes an application stored in the memory MR, an image data signal and/or an input control signal may be transmitted to the display module DM, and the display module DM may process the received signal and output image information through a display screen.

The power module PM may include a power supply module, such as a power adapter and/or a battery device, and a power conversion module configured or provided to convert power supplied by the power supply module to generate power required for operating the electronic device EA.

At least one of the components of the electronic device EA may be included in a display device according to one or more embodiments. Furthermore, one or more of the individual modules functionally included inside one module may be included inside the display device, and the others thereof may be provided separately from the display device. For example, the display device may include the display module DM, and the processor PR, the memory MR, and the power module PM may be provided in the form of other devices in the electronic device EA rather than the display device.

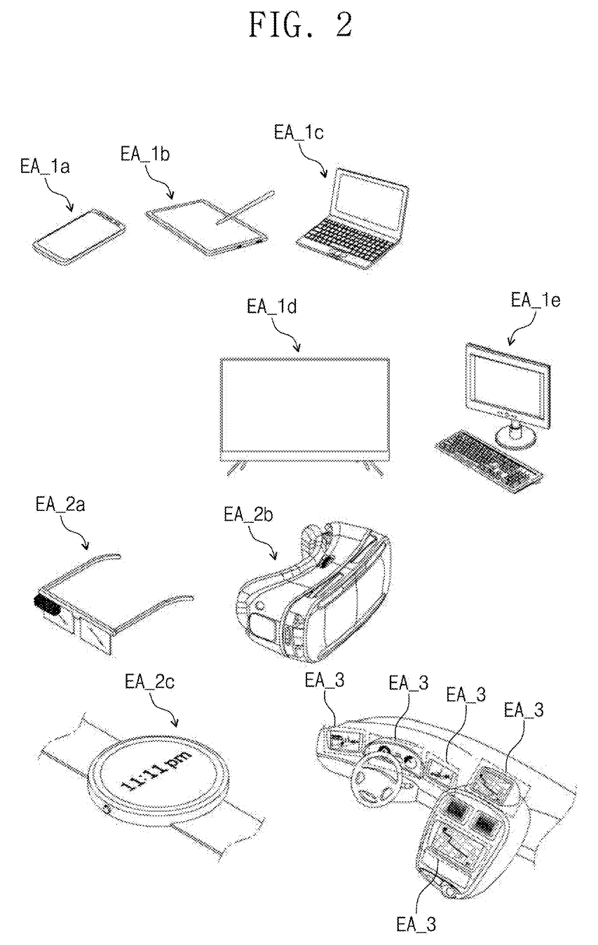

FIG. 2 is a schematic view of the electronic device according to one or more embodiments. Referring to FIG. 2, various suitable electronic devices to which the display device is applied according to one or more embodiments may include an image display electronic device, such as a smartphone EA_1a, a tablet (PC) EA_1b, a laptop computer EA_1c, a television (TV) EA_1d, and a desk monitor EA_1e, a wearable electronic device including a display module such as a smart glasses EA_2a, a head mounted display EA_2b, and a smart watch EA_2c, and a vehicle electronic device EA_3 including a display module, such as an instrument panel, a center fascia, a center information display (CID) on a dashboard, and a room mirror display of a vehicle.

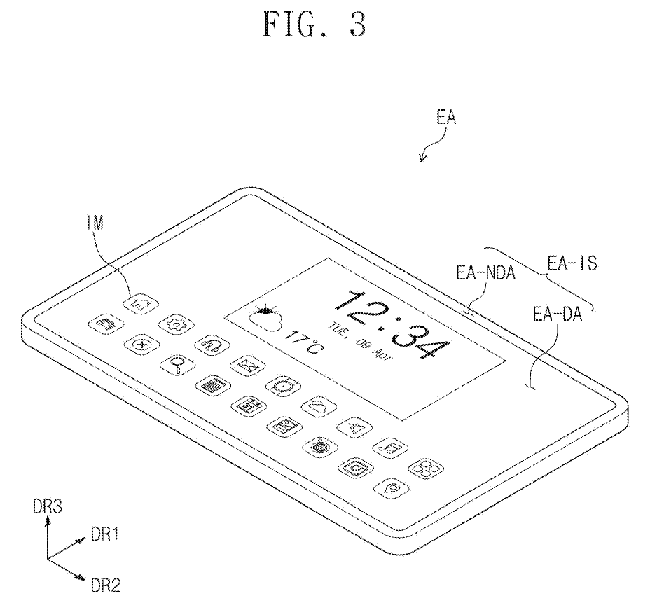

FIG. 3 is a perspective view illustrating an electronic device according to one or more embodiments. The electronic device EA according to one or more embodiments illustrated in FIG. 3 may be a device that is activated according to an electrical signal. Examples of the electronic device EA may include a personal computer, a laptop computer, a personal digital terminal, a game console, a portable electronic device, a television, a monitor, an external billboard, a vehicle navigation system, or a wearable device, but embodiments are not limited thereto. FIG. 3 illustrates, by way of example, that the electronic device EA is a television or tablet.

The electronic device EA may provide an image IM to a user through a display surface EA-IS. The display surface EA-IS may be parallel to a plane defined by a first direction axis DR1 and a second direction axis DR2. The electronic device EA may display the image IM in a third direction axis DR3. The image IM may include a still image as well as a dynamic image. FIG. 3 illustrates the electronic device EA having the flat display surface EA-IS, but embodiments are not limited thereto. For example, the electronic device EA may include a curved display surface or a three-dimensional display surface. The three-dimensional display surface may include a plurality of display areas indicating different directions.

The directions indicated by the first direction axis DR1, the second direction axis DR2, and the third direction axis DR3 described in the specification are relative concepts and may be changed to other directions. Furthermore, the directions indicated by the first direction axis DR1, the second direction axis DR2, and the third direction axis DR3 may be described as a first direction, a second direction, and a third direction, and the same reference numerals may be used therefor.

In the specification, the first direction axis DR1 and the second direction axis DR2 may be perpendicular to each other, and the third direction axis DR3 may be a normal direction to the plane defined by the first direction axis DR1 and the second direction axis DR2. A thickness direction of the electronic device EA may be a direction parallel to the third direction axis DR3. The thickness direction of the electronic device EA may use the same reference numeral as that of the third direction axis DR3. A front surface (or an upper surface) and a rear surface (or a lower surface) may be opposite to each other in the third direction axis DR3, and a normal direction of each of the front surface (or the upper surface) and the rear surface (or the lower surface) may be parallel to the third direction axis DR3. The front surface (or the upper surface) means a surface adjacent to the display surface EA-IS, and the rear surface (or the lower surface) means a surface spaced apart from the display surface EA-IS. An upper side means a direction closer to the display surface EA-IS, and a lower side means a direction away from the display surface EA-IS.

In the specification, a cross-section means a surface parallel to the thickness direction DR3. The plane means a plane perpendicular to the thickness direction DR3 and parallel to the plane defined by the first direction axis DR1 and the second direction axis DR2.

In the specification, the fact that a first component overlaps a second component means that the first component overlaps the second component on a plane. Furthermore, the fact that a first component overlaps a second component is not limited to an embodiment in which the first component and the second component have the same area and/or the same shape and includes an embodiment in which the first component and the second component have different areas and/or different shapes.

The electronic device EA may sense an external input applied from the outside. The external input may include various suitable types (or kinds) of inputs provided from the outside of the electronic device EA. For example, the external input may include a contact by a part of a body of the user such as a hand as well as an external input (e.g., hovering) applied close to the electronic device EA or adjacent to the electronic device EA at a constant distance. Furthermore, the external input may have various suitable forms such as a force, a pressure, a temperature, a light, or a combination thereof.

The display surface EA-IS may include a display area EA-DA and a non-display area EA-NDA. The electronic device EA may display the image IM through the display area EA-DA.

The display area EA-DA may be an area that is activated according to an electrical signal. The display area EA-DA may be an area in which the image IM may be displayed and one or more suitable forms of external inputs may be sensed.

The display area EA-DA may include the plane defined by the first direction axis DR1 and the second direction axis DR2. In one or more embodiments, the display area EA-DA may include a curved surface bent from at least one side of the plane defined by the first direction axis DR1 and the second direction axis DR2. For example, the display area EA-DA may further include at least two surfaces of the plane defined by the first direction axis DR1 and the second direction axis DR2 (e.g., four curved surfaces bent from four side surfaces thereof).

The electronic device EA according to one or more embodiments may be flexible. The wording “flexible” may mean a bendable property (e.g., being bendable) and includes both a structure that is completely folded and a structure that may be bent by several nanometers. For example, the electronic device EA may be a rigid device. In one or more embodiments, the electronic device EA may also be a foldable device.

The non-display area EA-NDA may have a color. The non-display area EA-NDA may be an area adjacent to the display area EA-DA. The non-display area EA-NDA may be around (e.g., surround) the display area EA-DA. Accordingly, a shape of the display area EA-DA may be substantially defined by the non-display area EA-NDA. However, FIG. 3 is illustrated by way of example, and the non-display area EA-NDA may be adjacent to only one side of the display area EA-DA or may not be provided. The display area EA-DA may be provided in various suitable shapes and is not limited to those described in one or more embodiments.

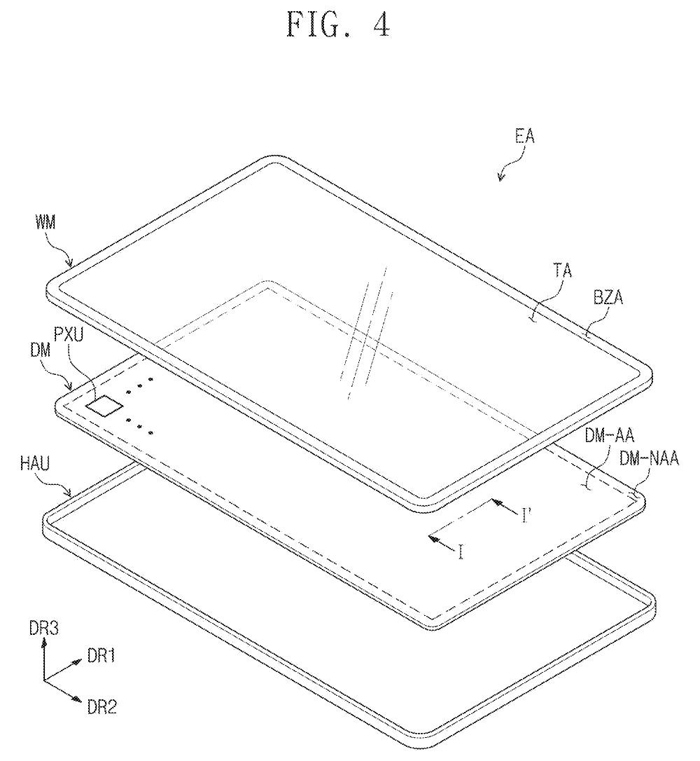

FIG. 4 is an exploded perspective view illustrating the electronic device according to one or more embodiments. Referring to FIG. 4, the electronic device EA may include the display module DM. Furthermore, the electronic device EA may further include a window member WM and a housing HAU.

The window member WM may be on the display module DM. The window member WM may cover the entire outer side of the electronic device EA. The window member WM may include a transmissive area TA and a bezel area BZA. A front surface of the window member WM including the transmissive area TA and the bezel area BZA may correspond to a front surface of the electronic device EA. The transmissive area TA may correspond to the display area EA-DA of the electronic device EA illustrated in FIG. 3, and the bezel area BZA may correspond to the non-display area EA-NDA of the electronic device EA illustrated in FIG. 3.

The transmissive area TA may be an optically transparent area. The bezel area BZA may be an area having a relatively low light transmittance as compared to the transmissive area TA. The bezel area BZA may have a color. The bezel area BZA may be adjacent to the transmissive area TA and may be around (e.g., surround) the transmissive area TA. The bezel area BZA may define a shape of the transmissive area TA. However, one or more embodiments are not limited to the illustration, the bezel area BZA may be adjacent to only one side of the transmissive area TA, and a portion thereof may not be provided.

The housing HAU may include a material having a relatively high rigidity. For example, the housing HAU may include a frame and/or a plate made of glass, plastic (e.g., polymer), and/or metal. The frame and/or plate may be provided as a plurality of frames and/or plates. The housing HAU may provide an accommodation space. The display module DM may be accommodated inside the accommodation space and protected from an external impact.

The display module DM may be activated according to an electrical signal and may provide the image IM (see FIG. 3). The display module DM may be activated to display the image IM (see FIG. 3) on the display area EA-DA (see FIG. 3) of the electronic device EA. An active area DM-AA and a peripheral area DM-NAA may be defined in the display module DM.

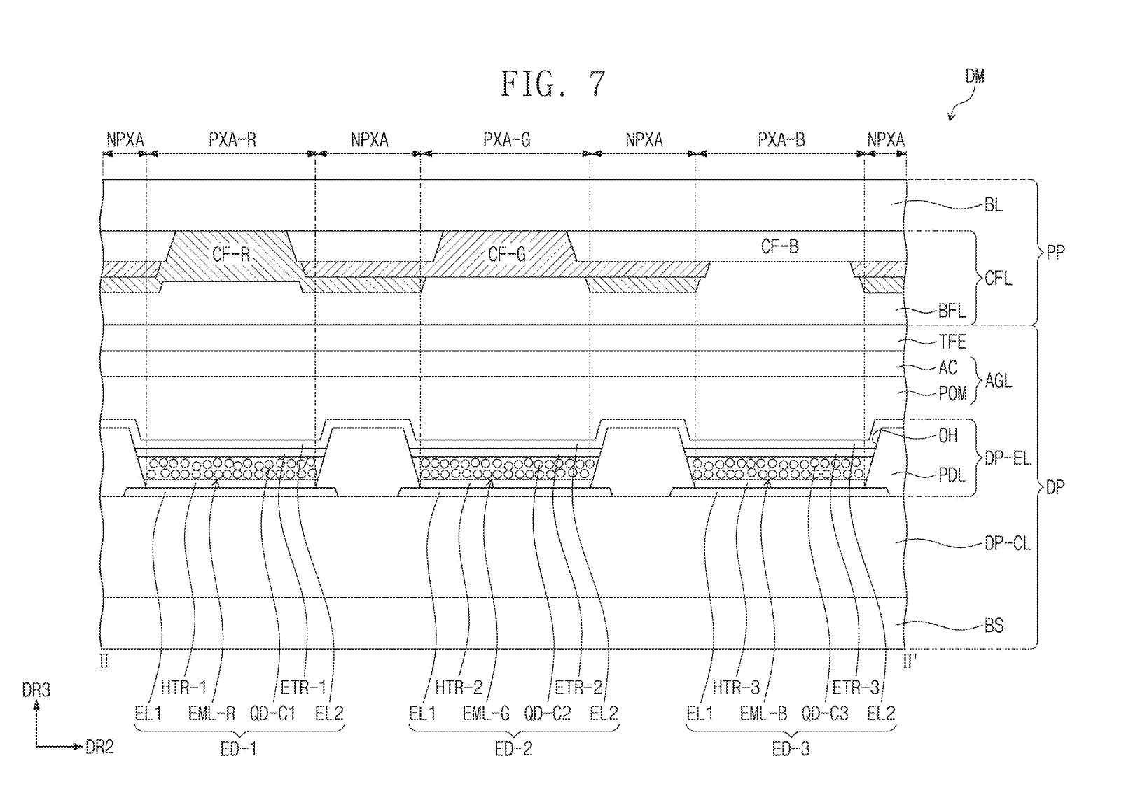

The active area DM-AA may be an area that is activated according to an electrical signal. A unit pixel PXU may be in the active area DM-AA. The pixel may include a transistor and light emitting elements ED-1, ED-2, and ED-3 (see FIG. 7). The peripheral area DM-NAA may be an area located to be adjacent to at least one side of the active area DM-AA. A circuit, a wiring line, and/or the like to drive the active area DM-AA may be in the peripheral area DM-NAA.

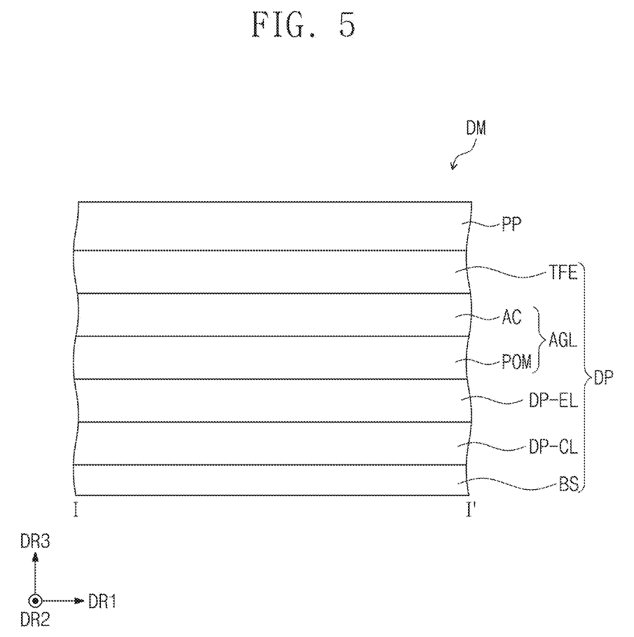

FIG. 5 is a cross-sectional view illustrating a portion corresponding to line I-I’ of FIG. 4. FIG. 5 may be a cross-sectional view illustrating the display module DM according to one or more embodiments.

The display module DM may include a display panel DP and an optical layer PP on the display panel DP. The display panel DP may include a base layer BS, a circuit layer DP-CL on the base layer BS, a display element layer DP-EL on the circuit layer DP-CL, an aging layer AGL on the display element layer DP-EL, and an encapsulation layer TFE on the aging layer AGL.

The display panel DP may be a component that substantially generates an image. The display panel DP may be a light emitting display panel. For example, the display panel DP may be a quantum dot light emitting display panel including a quantum dot light emitting element.

The base layer BS may provide a base surface for the circuit layer DP-CL. The base layer BS may be a rigid substrate or a flexible substrate that may be bent, folded, or rolled. The base layer BS may be a glass substrate, a metal substrate, a polymer substrate, and/or the like. However, one or more embodiments of the present disclosure are not limited thereto, and the base layer BS may be an inorganic layer, an organic layer, or a composite material layer (e.g., a composite layer including an inorganic layer and an organic layer).

The circuit layer DP-CL may be on the base layer BS. The circuit layer DP-CL may include an insulating layer (e.g., an electrically insulating layer), a semiconductor pattern, a conductive pattern (e.g., an electrically conductive pattern), a signal line, and/or the like. After the insulating layer, a semiconductor layer, and a conductive layer (e.g., an electrically conductive layer) are formed on the base layer BS by coating, deposition, and/or the like, the insulating layer, the semiconductor layer, and the conductive layer may be patterned (e.g., selectively patterned) through a plurality of photolithography processes. Thereafter, the semiconductor pattern, the conductive pattern, and the signal line included in the circuit layer DP-CL may be formed.

The display element layer DP-EL may be on the circuit layer DP-CL. The display element layer DP-EL may include a pixel defining film PDL (see FIG. 7) and the first light emitting element ED-1, the second light emitting element ED-2, and the third light emitting element ED-3 (see FIG. 7). For example, the display element layer DP-EL may include an organic light-emitting material, an inorganic light-emitting material, an organic-inorganic light-emitting material, a quantum dot, and/or a quantum rod. For example, the display element layer DP-EL may include a micro light emitting diode (LED) and/or a nano LED. In one or more embodiments, the display element layer DP-EL may include a quantum dot.

The aging layer AGL may be on the display element layer DP-EL. The aging layer AGL may be on the display element layer DP-EL to contribute to a positive aging effect. The aging layer AGL may include a porous film POM and a coating film AC. The porous film POM may be on the display element layer DP-EL. The coating film AC may be on the porous film POM.

The encapsulation layer TFE may be on the aging layer AGL. The encapsulation layer TFE may protect the display element layer DP-EL and the aging layer AGL from foreign substances such as moisture, oxygen, and/or dust particles. The encapsulation layer TFE may include at least one inorganic layer. The encapsulation layer TFE may include a structure in which an inorganic layer, an organic layer, and an inorganic layer are sequentially laminated.

The optical layer PP may be on the display panel DP to control reflected light from the display panel DP by external light. The optical layer PP may include, for example, a polarizing layer and/or a color filter layer. In one or more embodiments, the optical layer PP may not be provided.

The display module DM may further include an input sensing layer between the display panel DP and the optical layer PP. The input sensing layer may sense an external input, convert the sensed external input into an input signal, and provide the input signal to the display panel DP. For example, the input sensing layer may be a touch sensing layer that senses touch. The input sensing layer may recognize a direct touch of the user, an indirect touch of the user, a direct touch of an object, an indirect touch of the object, and/or the like.

The input sensing layer may sense a position of a touch applied from the outside, a strength (e.g., pressure) of the touch, or a combination thereof. In one or more embodiments, the input sensing layer may have one or more suitable structures or may be formed of one or more suitable materials, and the present disclosure is not limited to one or more embodiments described herein. For example, the input sensing layer may sense an external input in a capacitive manner. The display panel DP may receive the input signal from the input sensing layer and generate an image corresponding to the input signal.

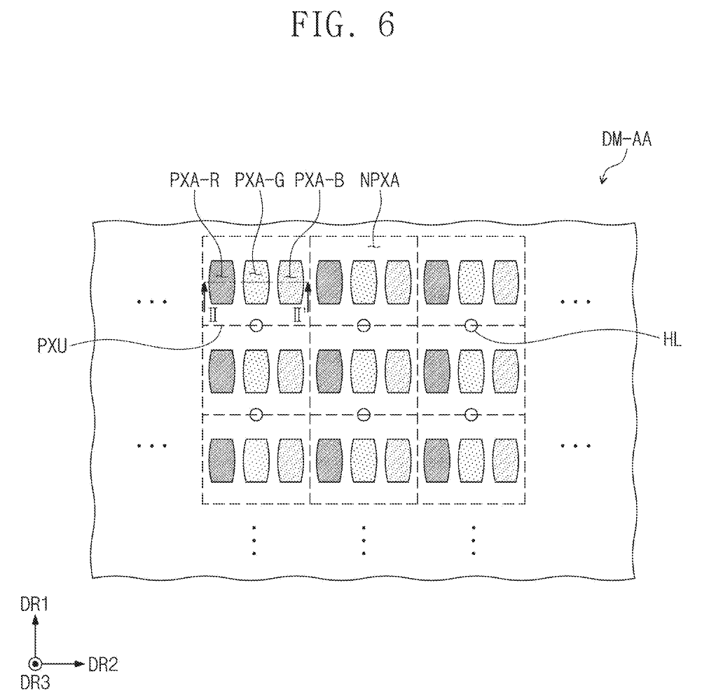

FIG. 6 is a schematic plan view of the active area DM-AA according to one or more embodiments. FIG. 6 illustrates, by way of example, a plane including three pixel areas PXA-R, PXA-G, and PXA-B and a light shielding area NPXA. The unit pixel PXU may include the first pixel area PXA-R, the second pixel area PXA-G, the third pixel area PXA-B, and the light shielding area NPXA. The unit pixel PXU may be repeatedly provided on the entire active area DM-AA illustrated in FIG. 4.

At least one hole HL may be between the unit pixels PXU. The hole HL may be an opening to adjust electron injection or hole injection. However, this is by way of example, and a role of the hole HL is not limited thereto. For example, the hole HL may be an opening to adjust a pressure in the display module DM (see FIG. 4). A size of the hole HL may be variously and suitably changed according to the role of the hole HL.

The hole HL may be between the second pixel areas PXA-G. The one hole HL may be between the two adjacent second pixel areas PXA-G in the first direction DR1. However, this is by way of example, and arrangement of the hole HL is not limited thereto.

The light shielding area NPXA may be around (e.g., surround) the first pixel area PXA-R, the second pixel area PXA-G, and the third pixel area PXA-B. The light shielding area NPXA may set boundaries between the first pixel area PXA-R, the second pixel area PXA-G, and the third pixel area PXA-B. The light shielding area NPXA may be around (e.g., surround) the first pixel area PXA-R, the second pixel area PXA-G, and the third pixel area PXA-B. A structure, e.g., the pixel defining film PDL (see FIG. 7), to prevent color mixing between the first pixel area PXA-R, the second pixel area PXA-G, and the third pixel area PXA-B may be in the light shielding area NPXA.

The pixel areas PXA-R, PXA-G, and PXA-B may be areas through which light generated by the light emitting elements ED-1, ED-2, and ED-3 (see FIG. 7) is emitted. FIG. 6 illustrates that the first pixel area PXA-R, the second pixel area PXA-G, and the third pixel area PXA-B have the same shape and the same area on a plane, but one or more embodiments are not limited thereto. Areas of at least two of the first pixel area PXA-R, the second pixel area PXA-G, and the third pixel area PXA-B may be different from each other. Areas of the first pixel area PXA-R, the second pixel area PXA-G, and the third pixel area PXA-B may be set according to colors of emitted light. An area of the pixel area that emits blue light, among primary colors, may be the narrowest. The area may mean an area on a plane.

FIG. 6 illustrates that the first pixel area PXA-R, the second pixel area PXA-G, and the third pixel area PXA-B have a quadrangular shape in which two sides facing each other are curves on a plane. In one or more embodiments, the first pixel area PXA-R, the second pixel area PXA-G, and the third pixel area PXA-B may have different polygonal shapes, such as a rhombus or a pentagon. For example, the first pixel area PXA-R, the second pixel area PXA-G, and the third pixel area PXA-B may have a quadrangular shape having rounded corner areas. In some embodiments, the first pixel area PXA-R, the second pixel area PXA-G, and the third pixel area PXA-B may have different shapes on a plane.

FIG. 6 illustrates that the first pixel area PXA-R, the second pixel area PXA-G, and the third pixel area PXA-B are arranged in the same row. However, this is by way of example, and the arrangement of the first pixel area PXA-R, the second pixel area PXA-G, and the third pixel area PXA-B may be variously and suitably changed. For example, the second pixel area PXA-G may be arranged in a first row, and the first pixel area PXA-R and the third pixel area PXA-B may be arranged in a second row.

One of the first pixel area PXA-R, the second pixel area PXA-G, and the third pixel area PXA-B may emit first light, another one thereof may emit second light different from the first light, and the other one thereof may emit third light different from the first light and the second light. For example, the first pixel area PXA-R may emit red light, the second pixel area PXA-G may emit green light, and the third pixel area PXA-B may emit blue light. The first pixel area PXA-R may be referred to as a red pixel area, the second pixel area PXA-G may be referred to as a green pixel area, and the third pixel area PXA-B may be referred to as a blue pixel area.

FIG. 7 is a cross-sectional view illustrating a portion corresponding to line II-II' of FIG. 6. FIG. 7 may be a cross-sectional view illustrating a detailed configuration of the display module DM according to one or more embodiments.

Referring to FIG. 7, the base layer BS may include a single layer or a plurality of layers. For example, the base layer BS may include a three-layer structure of a polymer resin layer, an adhesive layer, and a polymer resin layer. For example, the polymer resin layer may include a polyimide-based resin. Furthermore, the polymer resin layer may include an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, a perylene-based resin, or a combination thereof. In the specification, a "~~-based" resin means a resin including a functional group of "~~." For example, the polyimide-based resin means that the polyimide-based resin includes a polyimide functional group.

The circuit layer DP-CL may include the insulating layer, the semiconductor layer, the conductive layer, the signal line, and/or the like. The circuit layer DP-CL may include a plurality of transistors. Each of the transistors may include a control electrode, an input electrode, and an output electrode. For example, the circuit layer DP-CL may include a switching transistor and a driving transistor to drive the light emitting elements ED-1, ED-2, and ED-3 of the display element layer DP-EL.

The display element layer DP-EL may include the first light emitting element ED-1, the second light emitting element ED-2, the third light emitting element ED-3, and the pixel defining film PDL. An opening OH may be defined in the pixel defining film PDL.

The pixel defining film PDL may define the pixel areas PXA-R, PXA-G, and PXA-B. The pixel areas PXA-R, PXA-G, and PXA-B may be distinguished from the light shielding area NPXA by the pixel defining film PDL.

The pixel defining film PDL may be formed of a polymer resin. For example, the pixel defining film PDL may include a polyacrylate-based resin and/or a polyimide-based resin. Furthermore, the pixel defining film PDL may be formed to further include an inorganic material in addition to the polymer resin. The pixel defining film PDL may be formed to include a light absorbing material or may be formed to include a black pigment and/or a black dye. The pixel defining film PDL formed to include the black pigment and/or the black dye may implement a black pixel defining film. When the pixel defining film PDL is formed, carbon black may be used as the black pigment and/or the black dye, but one or more embodiments are not limited thereto.

Furthermore, the pixel defining film PDL may be formed of an inorganic material. For example, the pixel defining film PDL may be formed of an inorganic material such as a silicon nitride (SiNₓ), a silicon oxide (SiOₓ), and/or a silicon nitride (SiOₓN_{y}).

The light emitting elements ED-1, ED-2, and ED-3 may include first electrodes EL1, light emitting layers EML-R, EML-G, and EML-B arranged on the first electrodes EL1, second electrodes EL2 arranged on the light emitting layers EML-R, EML-G, and EML-B, hole transport areas HTR-1, HTR-2, and HTR-3 arranged between the first electrodes EL1 and the second electrodes EL2, and electron transport areas ETR-1, ETR-2, and ETR-3 arranged between the first electrodes EL1 and the second electrodes EL2, respectively. The light emitting layers EML-R, EML-G, and EML-B may be arranged between the electron transport areas ETR-1, ETR-2, and ETR-3, and the hole transport areas HTR-1, HTR-2, and HTR-3.

The light emitting elements ED-1, ED-2, and ED-3 may include the first electrodes EL1, the hole transport areas HTR-1, HTR-2, and HTR-3 arranged on the first electrodes EL1, the light emitting layers EML-R, EML-G, and EML-B arranged on the hole transport areas HTR-1, HTR-2, and HTR-3, the electron transport areas ETR-1, ETR-2, and ETR-3 arranged on the light emitting layers EML-R, EML-G, and EML-B, and the second electrodes EL2 arranged on the electron transport areas ETR-1, ETR-2, and ETR-3. The hole transport areas HTR-1, HTR-2, and HTR-3 may be arranged between the first electrodes EL1 and the light emitting layers EML-R, EML-G, and EML-B, and the electron transport areas ETR-1, ETR-2, and ETR-3 may be arranged between the light emitting layers EML-R, EML-G, and EML-B and the second electrodes EL2.

However, this is by way of example, and a laminated structure of the light emitting element is not limited thereto. For example, the light emitting elements ED-1, ED-2, and ED-3 may include the first electrodes EL1, the electron transport areas ETR-1, ETR-2, and ETR-3 arranged on the first electrodes EL1, the light emitting layers EML-R, EML-G, and EML-B arranged on the electron transport areas ETR-1, ETR-2, and ETR-3, the hole transport areas HTR-1, HTR-2, and HTR-3 arranged on the light emitting layers EML-R, EML-G, and EML-B, and the second electrodes EL2 arranged on the hole transport areas HTR-1, HTR-2, and HTR-3. The electron transport areas ETR-1, ETR-2, and ETR-3 may be arranged between the first electrodes EL1 and the light emitting layers EML-R, EML-G, and EML-B, and the hole transport areas HTR-1, HTR-2, and HTR-3 may be arranged between the light emitting layers EML-R, EML-G, and EML-B and the second electrodes EL2.

At least a portion of the first electrode EL1 may be exposed through the opening OH of the pixel defining film PDL. The first electrode EL1 may be conductive (e.g., electrically conductive). The first electrode EL1 may be formed of a metal material, a metal alloy, and/or a conductive compound (e.g., an electrically conductive compound). The first electrode EL1 may be a cathode or an anode. However, one or more embodiments are not limited thereto. Furthermore, the first electrode EL1 may be a pixel electrode. The first electrode EL1 may be a transmissive electrode, a semi-transmissive electrode, or a reflective electrode. The first electrode EL1 may include Ag, Mg, Cu, Al, Pt, Pd, Au, Ni, Nd, Ir, Cr, Li, Ca, LiF, Mo, Ti, W, In, Sn, Zn, a compound of two or more selected therefrom, a mixture of two or more selected therefrom, an oxide thereof, or a combination thereof.

When the first electrode EL1 is a transmissive electrode, the first electrode EL1 may include a transparent metal oxide, for example, an indium tin oxide (ITO), an indium zinc oxide (IZO), a zinc oxide (ZnO), an indium tin zinc oxide (ITZO), and/or the like. When the first electrode EL1 is a semi-transmissive electrode or a reflective electrode, the first electrode EL1 may include Ag, Mg, Cu, Al, Pt, Pd, Au, Ni, Nd, Ir, Cr, Li, Ca, LiF, Mo, Ti, W, or a compound or mixture thereof (e.g., a mixture of Ag and Mg), or a material having a multilayer structure composed of two or more selected therefrom (e.g., LiF/Ca (a laminated structure of LiF and Ca), LiF/Al (a laminated structure of LiF and Al)). In one or more embodiments, the first electrode EL1 may have a multi-layer structure including a reflective film or a semi-transmissive film formed of the above material and a transparent conductive film formed of an indium tin oxide (ITO), an indium zinc oxide (IZO), a zinc oxide (ZnO), and/or an indium tin zinc oxide (ITZO). For example, the first electrode EL1 may have a three-layer structure of ITO/Ag/ITO, but the embodiments of the present disclosure are not limited thereto. Furthermore, the first electrode EL1 may include the above-described metal material, a combination of two or more metal materials selected from the above-described metal materials, and/or oxides of the above-described metal materials, and one or more embodiments are not limited thereto. A thickness of the first electrode EL1 may be in a range of about 700 Å to about 10,000 Å. For example, the thickness of the first electrode EL1 may be in a range of about 1,000 Å to about 3,000 Å.

The second electrode EL2 may be a common electrode. The second electrode EL2 may be an anode or a cathode, but one or more embodiments are not limited thereto. For example, when the first electrode EL1 is an anode, the second electrode EL2 may be a cathode, or when the first electrode EL1 is a cathode, the second electrode EL2 may be an anode. The second electrode EL2 may include Ag, Mg, Cu, Al, Pt, Pd, Au, Ni, Nd, Ir, Cr, Li, Ca, LiF, Mo, Ti, W, In, Sn, Zn, a compound of two or more selected therefrom, a mixture of two or more selected therefrom, an oxide thereof, or a combination thereof.

The second electrode EL2 may be a transmissive electrode, a semi-transmissive electrode, or a reflective electrode. When the second electrode EL2 is a transmissive electrode, the second electrode EL2 may be formed of a transparent metal oxide, for example, an indium tin oxide (ITO), an indium zinc oxide (IZO), a zinc oxide (ZnO), an indium tin zinc oxide (ITZO), and/or the like.

When the second electrode EL2 is a semi-transmissive electrode or a reflective electrode, the second electrode EL2 may include Ag, Mg, Cu, Al, Pt, Pd, Au, Ni, Nd, Ir, Cr, Li, Ca, LiF, Mo, Ti, Yb, W, or a compound or mixture (e.g., AgMg, AgYb, or MgYb) including the same or a material having a multilayer structure composed of two or more selected therefrom (e.g., LiF/Ca (a laminated structure of LiF and Ca), LiF/Al (a laminated structure of LiF and Al)). In one or more embodiments, the second electrode EL2 may have a multi-layer structure including a reflective film or a semi-transmissive film formed or provided of the above material and a transparent conductive film formed or provided of an indium tin oxide (ITO), an indium zinc oxide (IZO), a zinc oxide (ZnO), and an indium tin zinc oxide (ITZO). For example, the second electrode EL2 may include the above-described metal materials, a combination of two or more metal materials selected from the above-described metal materials, an oxide of the above-described metal materials, and/or the like.

The second electrode EL2 may be connected to the auxiliary electrode. When the second electrode EL2 is connected to the auxiliary electrode, resistance (e.g., electrical resistance) of the second electrode EL2 may be reduced.

The light emitting layers EML-R, EML-G, and EML-B may be arranged between the first electrode EL1 and the second electrode EL2. The first light emitting element ED-1 may include the first light emitting layer EML-R, the second light emitting element ED-2 may include the second light emitting layer EML-G, and the third light emitting element ED-3 may include the third light emitting layer EML-B. The first light emitting layer EML-R may include a first quantum dot QD-C1. The second light emitting layer EML-G may include a second quantum dot QD-C2. The third light emitting layer EML-B may include a third quantum dot QD-C3.

The first quantum dot QD-C1, the second quantum dot QD-C2, and the third quantum dot QD-C3 may be laminated to form a layer. FIG. 7 illustrates, by way of example, that the quantum dots QD-C1, QD-C2, and QD-C3 having a circular cross-section are arranged to approximately form two layers, but one or more embodiments are not limited thereto. For example, the arrangement of the quantum dots QD-C1, QD-C2, and QD-C3 may be changed depending on thicknesses of the light emitting layers EML-R, EML-G, and EML-B, shapes of the quantum dots QD-C1, QD-C2, and QD-C3 included in the light emitting layers EML-R, EML-G, and EML-B, average diameters of the quantum dots QD-C1, QD-C2, and QD-C3, and/or the like. In other embodiments, in the light emitting layers EML-R, EML-G, and EML-B, the quantum dots QD-C1, QD-C2, and QD-C3 may be aligned to be adjacent to each other so as to form one layer or form a plurality of layers, e.g., two layers or three layers.

The first quantum dot QD-C1 of the first light emitting element ED-1 may emit red light. The second quantum dot QD-C2 of the second light emitting element ED-2 may emit green light. The third quantum dot QD-C3 of the third light emitting element ED-3 may emit blue light. For example, each of the quantum dots QD-C1, QD-C2, and QD-C3 may include a core and a shell around (e.g., surrounding) the core. Accordingly, each of the quantum dots QD-C1, QD-C2, and QD-C3 may include a core-shell structure. The cores of the quantum dots QD-C1, QD-C2, and QD-C3 may include different materials. For example, the cores of the quantum dots QD-C1, QD-C2, and QD-C3 may include the same material. In one or more embodiments, two of the cores of the quantum dots QD-C1, QD-C2, and QD-C3 may include the same material, and the other one core may include a different material.

FIG. 7 illustrates that the first quantum dot QD-C1, the second quantum dot QD-C2, and the third quantum dot QD-C3 have similar diameters, but one or more embodiments are not limited thereto. The diameters of the first quantum dot QD-C1, the second quantum dot QD-C2, and the third quantum dot QD-C3 may be different from each other. For example, the third quantum dot QD-C3 of the third light emitting element ED-3 that emits light in a relatively short wavelength range may have a relatively small average diameter compared to the first quantum dot QD-C1 of the first light emitting element ED-1 and the second quantum dot QD-C2 of the second light emitting element ED-2 that emit light in a relatively long wavelength range. The average diameter means a value obtained by arithmetically averaging particle diameters of a plurality of quantum dots. The particle diameter of the quantum dot may be an average value of widths of quantum dot particles on a cross-section.

The hole transport areas HTR-1, HTR-2, and HTR-3 may be arranged between the first electrodes EL1 and the light emitting layers EML-R, EML-G, and EML-B. The hole transport areas HTR-1, HTR-2, and HTR-3 of the first light emitting element ED-1, the second light emitting element ED-2, and the third light emitting element ED-3 may be arranged in the opening OH and thus distinguished from each other. In one or more embodiments, the hole transport areas HTR-1, HTR-2, and HTR-3 of the first light emitting element ED-1, the second light emitting element ED-2, and the third light emitting element ED-3 may be provided as a common layer. The hole transport areas HTR-1, HTR-2, and HTR-3 provided as the common layer may overlap the pixel areas PXA-R, PXA-G, and PXA-B and the light shielding area NPXA. The first light emitting element ED-1 may include the first hole transport area HTR-1, the second light emitting element ED-2 may include the second hole transport area HTR-2, and the third light emitting element ED-3 may include the third hole transport area HTR-3.

Each of the first hole transport area HTR-1, the second hole transport area HTR-2, and the third hole transport area HTR-3 may have a single layer made of a single material, a single layer made of a plurality of different materials, or a multi-layer structure having a plurality of layers made of a plurality of different materials. A thickness of each of the first hole transport area HTR-1, the second hole transport area HTR-2, and the third hole transport area HTR-3 may be, for example, in a range of about 50 Å to about 15,000 Å. The thickness of each of the first hole transport area HTR-1, the second hole transport area HTR-2, and the third hole transport area HTR-3 may be in a range of 100 Å to 10,000 Å, for example, in a range of about 100 Å to about 5,000 Å.

The first hole transport area HTR-1, the second hole transport area HTR-2, and the third hole transport area HTR-3 may include any suitable hole injection material and/or any hole transport material generally available in the art. For example, the first hole transport area HTR-1, the second hole transport area HTR-2, and the third hole transport area HTR-3 may include a phthalocyanine compound, such as copper phthalocyanine, N1,N1'-([1,1'-biphenyl]-4,4'-diyl)bis(N1-phenyl-N4,N4’-di-m-tolylbenzene-1,4-diamine)(DNTPD), 4,4',4"-[tris(3-methylphenyl)phenylamino] triphenylamine (m-MTDATA), 4,4',4"-Tris(N,N-diphenylamino)triphenylamine (TDATA), 4,4',4"-tris[N-(2-naphthyl)-N-phenylamino]-triphenylamine (2-TNATA), Poly(3,4-ethylenedioxythiophene)/Poly(4-styrenesulfonate)(PEDOT/PSS), Polyaniline/Dodecylbenzenesulfonic acid (PANI/DBSA), Polyaniline/Poly(4-styrenesulfonate)(PANI/PSS), N,N'-di(naphthalene-1-yl)-N,N'-diphenyl-benzidine (NPB), polyetherketone (TPAPEK) containing triphenylamine, 4-Isopropyl-4'-methyldiphenyliodonium [Tetrakis(pentafluorophenyl)borate], and/or dipyrazino[2,3-f: 2',3'-h] quinoxaline-2,3,6,7,10,11-hexacarbonitrile (HATCN).

Furthermore, the first hole transport area HTR-1, the second hole transport area HTR-2, and the third hole transport area HTR-3 may include a carbazole-based derivative, such as N-phenylcarbazole and polyvinylcarbazole, a fluorene-based derivative, N,N'-bis(3-methylphenyl)-N,N'-diphenyl-[1,1'-biphenyl]-4,4'-diamine (TPD), a triphenylamine-based derivative such as 4,4',4"-tris(N-carbazolyl)triphenylamine (TCTA), N,N'-di(naphthalene-1-yl)-N,N'-diphenyl-benzidine (NPB), 4,4′-Cyclohexylidene bis[N,N-bis(4-methylphenyl)benzenamine](TAPC), 4,4'-Bis[N,N'-(3-tolyl)amino]-3,3'-dimethylbiphenyl (HMTPD), 9-(4-tert-Butylphenyl)-3,6-bis(triphenylsilyl)-9H-carbazole (CzSi), 9-phenyl-9H-3,9’-bicarbazole (CCP), 1,3-Bis(N-carbazolyl)benzene (mCP), 1,3-bis(1,8-dimethyl-9H-carbazol-9-yl)benzene (mDCP), and/or the like.

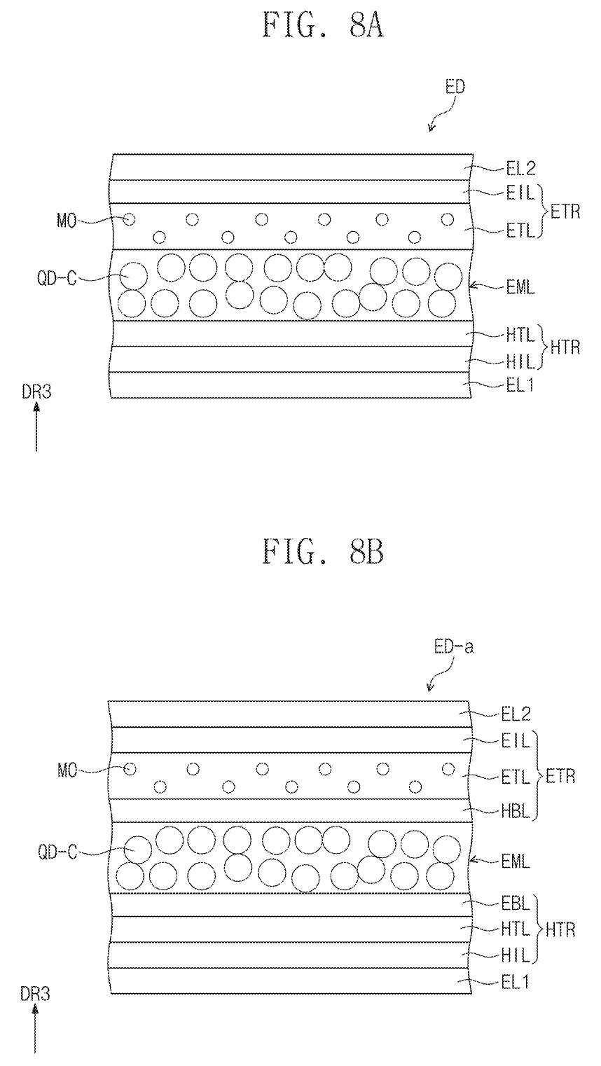

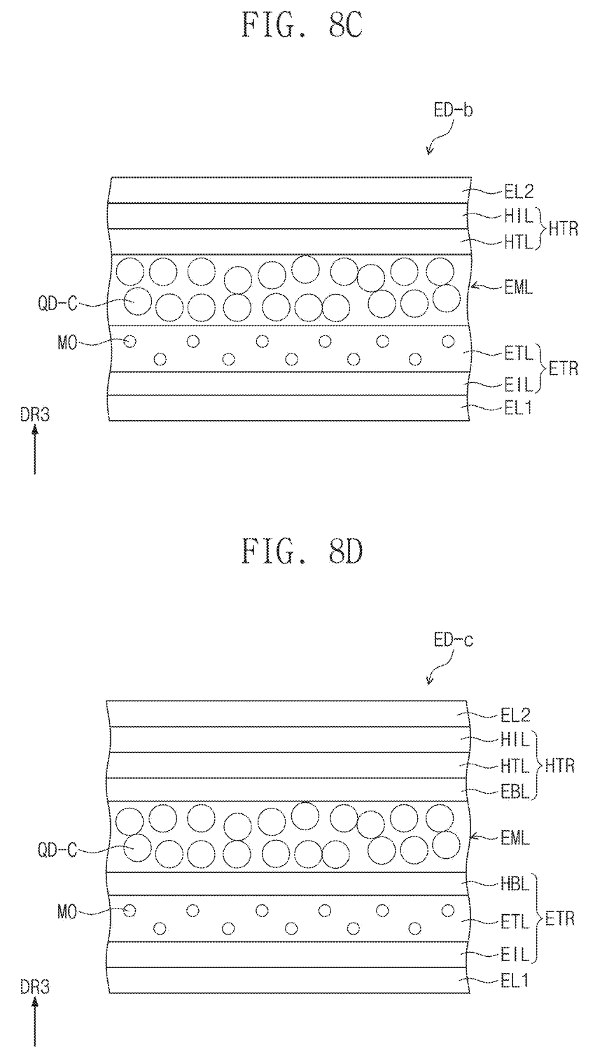

The electron transport areas ETR-1, ETR-2, and ETR-3 may be arranged between the light emitting layers EML-R, EML-G, and EML-B and the second electrodes EL2. In one or more embodiments, the electron transport areas ETR-1, ETR-2, and ETR-3 may include a metal oxide MO (see FIGS. 8A-8D).

The electron transport areas ETR-1, ETR-2, and ETR-3 of the first light emitting element ED-1, the second light emitting element ED-2, and the third light emitting element ED-3 may be arranged in the opening OH and thus distinguished from each other. In one or more embodiments, the electron transport areas ETR-1, ETR-2, and ETR-3 of the first light emitting element ED-1, the second light emitting element ED-2, and the third light emitting element ED-3 may be provided as a common layer. The electron transport areas ETR-1, ETR-2, and ETR-3 provided as the common layer may overlap the pixel areas PXA-R, PXA-G, and PXA-B and the light shielding area NPXA. The first light emitting element ED-1 may include the first electron transport area ETR-1, the second light emitting element ED-2 may include the second electron transport area ETR-2, and the third light emitting element ED-3 may include the third electron transport area ETR-3.

Each of the first electron transport area ETR-1, the second electron transport area ETR-2, and the third electron transport area ETR-3 may have a single layer made of a single material, a single layer made of a plurality of different materials, or a multi-layer structure having a plurality of layers made of a plurality of different materials. A thickness of each of the first electron transport area ETR-1, the second electron transport area ETR-2, and the third electron transport area ETR-3 may be, for example, in a range of about 1,000 Å to about 1,500 Å.

The first electron transport area ETR-1, the second electron transport area ETR-2, and the third electron transport area ETR-3 may include any suitable electron injection material and/or any suitable electron transport material generally available in the art. For example, the first electron transport area ETR-1, the second electron transport area ETR-2, and the third electron transport area ETR-3 may include an anthracene-based compound. In one or more embodiments, the first electron transport area ETR-1, the second electron transport area ETR-2, and the third electron transport area ETR-3 may include, for example, Tris(8-hydroxyquinolinato)aluminum (Alq3), 1,3,5-tri[(3-pyridyl)-phen-3-yl]benzene, 2,4,6-tris(3'-(pyridin-3-yl)biphenyl-3-yl)-1,3,5-triazine, 2-(4-(N-phenylbenzoimidazol-1-yl)phenyl)-9,10-dinaphthylanthracene, 1,3,5-Tri(1-phenyl-1H-benzo[d]imidazol-2-yl)benzene (TPBi), 2,9-Dimethyl-4,7-diphenyl-1,10-phenanthroline (BCP), 4,7-Diphenyl-1,10-phenanthroline (Bphen), 3-(4-Biphenylyl)-4-phenyl-5-tert-butylphenyl-1,2,4-triazole (TAZ), 4-(Naphthalen-1-yl)-3,5-diphenyl-4H-1,2,4-triazole (NTAZ), 2-(4-Biphenylyl)-5-(4-tert-butylphenyl)-1,3,4-oxadiazole (tBu-PBD), Bis(2-methyl-8-quinolinolato-N1,O8)-(1,1'-Biphenyl-4-olato)aluminum (BAlq), berylliumbis(benzoquinolin-10-olate)(Bebq2), 9,10-di(naphthalene-2-yl)anthracene (ADN), 1,3-Bis[3,5-di(pyridin-3-yl)phenyl]benzene (BmPyPhB), and/or a mixture thereof. In one or more embodiments, the first electron transport area ETR-1, the second electron transport area ETR-2, and the third electron transport area ETR-3 may include 2,9-dimethyl-4,7-diphenyl-1,10-phenanthroline (BCP), diphenyl(4-(triphenylsilyl)phenyl)phosphine oxide (TSPO1), 4,7-diphenyl-1,10-phenanthroline (Bphen), and/or the like.

The aging layer AGL may be on the light emitting elements ED-1, ED-2, and ED-3 to contribute to a positive aging effect. Accordingly, the electronic device EA (see FIG. 3) including the aging layer AGL according to one or more embodiments may exhibit excellent or suitable display quality and excellent or suitable reliability.

In the specification, the fact that a first component is directly provided/formed on a second component means that a third component is not provided/formed between the first component and the second component. For example, the fact that a first component is directly provided/formed on a second component means that the first component and the second component are in contact with each other.

The aging layer AGL may be directly on the light emitting elements ED-1, ED-2, and ED-3. The aging layer AGL may be a laminate film. Thus, the aging layer AGL may be attached onto the light emitting elements ED-1, ED-2, and ED-3 after being formed by a separate process.

The aging layer AGL may include the porous film POM and the coating film AC. The porous film POM may be on the light emitting elements ED-1, ED-2, and ED-3. The coating film AC may be on the porous film POM.

The coating film AC may include an organic acid. The organic acid may include a methacrylic acid, an acrylic acid, a citric acid, or a combination thereof. Furthermore, the organic acid may include a carboxyl group. However, this is by way of example, and one or more embodiments are not limited thereto. For example, the coating film AC may include an organic acid containing a functional group other than a carboxyl group.

In the light emitting element according to the related art, the electron transport area includes a metal oxide. The metal oxide may have oxygen vacancy defects as oxygen atoms escape therefrom. The oxygen vacancy defects in the metal oxide cause electrons and holes to be recoupled at low energy levels. Accordingly, the light emitting element emits defect light emission, an electron capture phenomenon occurs, and thus electron mobility is reduced. Thus, the light emitting element according to the related art exhibits low luminous efficiency, a high driving voltage, and a short lifetime.

According to one or more embodiments, in the electronic device EA (see FIG. 3), the aging layer AGL including the coating film AC may be on the light emitting elements ED-1, ED-2, and ED-3. The coating film AC including the organic acid according to one or more embodiments may contribute to a decrease in defects and improved electron mobility of the light emitting elements ED-1, ED-2, and ED-3.

When heat is applied to the coating film AC, the acid in the coating film AC may be volatilized and discharged in the form of an acidic fume. The acidic fume may mean fine acidic particles. The discharged acidic fume may pass through the porous film POM and may be diffused into the light emitting elements ED-1, ED-2, and ED-3. The acidic fume may passivate the oxygen vacancy defects in the metal oxide MO (see FIGS. 8A-8D) included in the electron transport areas ETR-1, ETR-2, and ETR-3. Accordingly, in the light emitting elements ED-1, ED-2, and ED-3, defect light emission may be suppressed or reduced, an electron capture phenomenon may be reduced, and electron mobility may be increased. Thus, the coating film AC may contribute to high luminous efficiency, a low driving voltage, and a long lifetime of the light emitting elements ED-1, ED-2, and ED-3.

The coating film AC may further include a polymer matrix. The polymer matrix may uniformly (e.g., substantially uniformly) disperse the acid fume. Thus, the polymer matrix may contribute to a uniform (e.g., substantially uniform) aging effect of the light emitting elements ED-1, ED-2, and ED-3. Furthermore, the polymer matrix may allow the coating film AC to adhere to the porous film POM.

The porous film POM may be a film through which the acid fume generated from the coating film AC passes. The porous film POM may be between the coating film AC and the light emitting elements ED-1, ED-2, and ED-3 and cause the acidic fume to be generated at a distance from the light emitting elements ED-1, ED-2, and ED-3.

The porous film POM may have a thickness in a range of 5μm to 100μm. The porous film POM having a thickness of less than 5μm has an incomplete pore structure. Thus, when the acidic fume formed in the coating film passes through the porous film POM having a thickness of less than 5μm, the acidic fume is not uniformly diffused into the light emitting element. Accordingly, an aging effect does not uniformly occur in the light emitting element, an excessive aging effect occurs only in a specific area of the light emitting element, and thus stains occur on a surface of the display panel. The porous film POM having a thickness greater than 100μm delays diffusion of the acid fume formed in the coating film into the light emitting element. Therefore, the aging effect of the light emitting element is degraded.

In one or more embodiments, the porous film POM having a thickness in a range of 5 μm to 100 μm may allow the acidic fume formed in the coating film AC to be quickly and uniformly (e.g., substantially uniformly) diffused into the light emitting elements ED-1, ED-2, and ED-3. Thus, the porous film POM according to one or more embodiments may contribute to a uniform (e.g., substantially uniform) and improved aging effect of the light emitting elements ED-1, ED-2, and ED-3 and may prevent or reduce the occurrence of stains on the surface of the display panel DP. Accordingly, the electronic device EA (see FIG. 3) including the porous film POM according to one or more embodiments may exhibit excellent or suitable reliability and excellent or suitable display quality.

The porous film POM may include a polymer, a ceramic, or a combination thereof. The polymer may include polydimethylsiloxane. Furthermore, the ceramic may include a silicon oxy carbide. However, this is by way of example, and a material of the porous film POM is not limited thereto.

The encapsulation layer TFE may include at least one inorganic layer (hereinafter, referred to as an inorganic encapsulation film). Furthermore, the encapsulation layer TFE may include at least one organic film (hereinafter, an organic encapsulation film) and at least one inorganic encapsulation film.

The inorganic encapsulation film may protect the display element layer DP-EL and the aging layer AGL from moisture/oxygen, and the organic encapsulation film may protect the display element layer DP-EL and the aging layer AGL from foreign substances, such as dust particles and the like. The inorganic encapsulation film may include a silicon nitride, a silicon oxy nitride, a silicon oxide, a titanium oxide, and/or an aluminum oxide, but the present disclosure is not particularly limited thereto. The organic encapsulation film may include an acryl-based compound, an epoxy-based compound, and/or the like. The organic encapsulation film may include an organic material capable of photopolymerization, but the present disclosure is not particularly limited thereto.

The optical layer PP may include a base substrate BL and a color filter layer CFL. The base substrate BL may provide a base surface for the color filter layer CFL. The base substrate BL may be a glass substrate, a metal substrate, and a plastic substrate (e.g., a polymer substrate). However, one or more embodiments are not limited thereto, and the base substrate BL may be an inorganic layer, an organic layer, or a composite material layer (e.g., a composite material layer including an inorganic layer and an organic layer).

The color filter layer CFL may include a first filter CF-R, a second filter CF-G, and a third filter CF-B. The first filter CF-R, the second filter CF-G, and the third filter CF-B may be arranged to correspond to the first light emitting element ED-1, the second light emitting element ED-2, and the third light emitting element ED-3, respectively. For example, the first filter CF-R may be a red filter, the second filter CF-G may be a green filter, and the third filter CF-B may be a blue filter. The first filter CF-R, the second filter CF-G, and the third filter CF-B may be arranged to correspond to the first pixel area PXA-R, the second pixel area PXA-G, and the third pixel area PXA-B, respectively.

Each of the first filter CF-R, the second filter CF-G, and the third filter CF-B may be a polymer photosensitive resin and a pigment and/or a dye. The first filter CF-R may include a red pigment and/or a red dye, the second filter CF-G may include a green pigment and/or a green dye, and the third filter CF-B may include a blue pigment and/or a blue dye. However, one or more embodiments are not limited thereto, and the third filter CF-B may not include a pigment or a dye. The third filter CF-B may include a polymer photosensitive resin and may not include a pigment or a dye. The third filter CF-B may be transparent. The third filter CF-B may be formed of a transparent photosensitive resin.

The color filter layer CFL may further include a buffer layer BFL. For example, the buffer layer BFL may be a protective layer that protects the first filter CF-R, the second filter CF-G, and the third filter CF-B. The buffer layer BFL may be between the encapsulation layer TFE and the first filter CF-R, the second filter CF-G, and the third filter CF-B. The buffer layer BFL may be an inorganic layer including an inorganic material selected from a silicon nitride, a silicon oxide, a silicon oxy nitride, or a combination thereof. The buffer layer BFL may include a single layer or a plurality of layers.

Furthermore, the first filter CF-R and the second filter CF-G may be yellow filters. The first filter CF-R and the second filter CF-G may be provided integrally without being distinguished from each other.

The color filter layer CFL may further include a light shielding part. The light shielding part may be a black matrix. The light shielding part may be formed to include an organic light shielding material and/or an inorganic light shielding material including a black pigment and/or a black dye. The light shielding part may prevent or reduce light leakage and divide boundaries between the adjacent filters CF-R, CF-G, and CF-B.

FIGS. 8A-8D are cross-sectional views illustrating light emitting elements ED, ED-a, ED-b, and ED-c according to one or more embodiments. Referring to FIGS. 8A-8D, the light emitting elements ED, ED-a, ED-b, and ED-c may include the first electrode EL1, a light emitting layer EML on the first electrode EL1, the second electrode EL2 on the light emitting layer EML, a hole transport area HTR between the first electrode EL1 and the second electrode EL2, and an electron transport area ETR between the first electrode EL1 and the second electrode EL2. The light emitting layer EML may be between the electron transport area ETR and the hole transport area HTR.

At least one chosen from the light emitting elements ED and ED-a described with reference to FIGS. 8A and 8B may be equally applied to at least one chosen from the first light emitting element ED-1, the second light emitting element ED-2, and the third light emitting element ED-3 illustrated in FIG. 7. The light emitting elements ED-b and ED-c of FIGS. 8C and 8D are different from the light emitting elements ED and ED-a of FIGS. 8A and 8B in terms of arrangement positions of the hole transport area HTR and the electron transport area ETR. At least one chosen from the light emitting elements ED-b and ED-c described with reference to FIGS. 8C and 8D may be applied to at least one chosen from the first light emitting element ED-1, the second light emitting element ED-2, and the third light emitting element ED-3 illustrated in FIG. 7.

Referring to FIGS. 8A and 8B, the light emitting elements ED and ED-a may include the first electrode EL1, the hole transport area HTR, the light emitting layer EML, the electron transport area ETR, and the second electrode EL2, which are sequentially laminated. The hole transport area HTR may include a hole injection layer HIL and a hole transport layer HTL on the hole injection layer HIL. The electron transport area ETR may include an electron transport layer ETL and an electron injection layer EIL on the electron transport layer ETL.

In the light emitting element ED-a illustrated in FIG. 8B, the hole transport area HTR may further include an electron blocking layer EBL on the hole transport layer HTL. The electron transport area ETR may further include a hole blocking layer HBL between the light emitting layer EML and the electron transport layer ETL.

Referring to FIGS. 8C and 8D, the light emitting elements ED-b and ED-c may include the first electrode EL1, the electron transport area ETR, the light emitting layer EML, the hole transport area HTR, and the second electrode EL2, which are sequentially laminated. The electron transport area ETR may include the electron injection layer EIL and the electron transport layer ETL on the electron injection layer EIL. The hole transport area HTR may include the hole transport layer HTL and the hole injection layer HIL on the hole transport layer HTL.

In the light emitting element ED-c illustrated in FIG. 8D, the electron transport area ETR may further include the hole blocking layer HBL on the electron transport layer ETL. The hole transport area HTR may further include the electron blocking layer EBL between the light emitting layer EML and the hole transport layer HTL.

The electron injection layer EIL may not be provided, contrary to the illustrations in FIGS. 8A-8D. Any one of the hole injection layer HIL and the hole transport layer HTL may not be provided.

The electron transport area ETR may include the metal oxide MO according to one or more embodiments. In more detail, the electron transport layer ETL may include the metal oxide MO according to one or more embodiments.

The metal oxide MO may include SnO, SnO₂, CuGaO₂, Ga₂O₃, Cu₂O, SrCu₂O₂, SrTiO₃, CuAlO₂, Ta₂O₅, NiO, BaSnO₃, TiO₂, a compound represented by the following chemical formula M-1, or a combination thereof.
[Chemical formula M-1]
Zn_{(1-q)}Me_{q}O

In Chemical formula M-1, q may be 0 or more and 0.5 or less, and Me may be Li, Be, Na, Mg, Al, K, Ca, Ti, V, Cr, Mn, Fe, Co, Ni, Cu, Ga, Ge, Rb, Sr, Zr, Nb, Mo, Ru, Pd, Ag, In, Sn(II), Sn(IV), Sb, or Ba.

As described above, the metal oxide MO may correspond to a state in which oxygen vacancy defects are passivated by the acid fume formed in the aging layer AGL (see FIG. 7). The light emitting elements ED, ED-a, ED-b, and ED-c including the metal oxide MO in which oxygen vacancy defects are passivated may exhibit high luminous efficiency, a low driving voltage, and a long lifetime. Accordingly, the electronic device EA (see FIG. 3) including the light emitting elements ED, ED-a, ED-b, and ED-c and the aging layer AGL (see FIG. 7) according to one or more embodiments may exhibit excellent or suitable reliability.

The light emitting layer EML may include a quantum dot QD-C. Hereinafter, a description of the quantum dot QD-C may be equally applied to the first quantum dot QD-C1, the second quantum dot QD-C2, and the third quantum dot QD-C3 illustrated in FIG. 7.

In the specification, the quantum dot QD-C may mean a crystal of a semiconductor compound. The quantum dot QD-C may emit light having one or more suitable light emitting wavelengths according to a size of the crystal. A diameter of the quantum dot QD-C may be, for example, in a range of about 1nm to about 10nm.

The quantum dot QD-C may be synthesized by a wet chemical process, a metal organic chemical vapor deposition (MOCVD) process, a molecular beam epitaxy (MBE) process, and/or a process similar thereto. The wet chemical process is a method of growing particle crystals of the quantum dot QD-C after mixing an organic solvent and a precursor material. When the crystals are grown, the organic solvent may serve as a dispersant that is naturally coordinated to crystal surfaces of the quantum dot QD-C and adjust the growth of the crystals. Thus, the wet chemical process may control the growth of particles of the quantum dot QD-C through a low-cost process more easily than a vapor deposition process, such as the metal organic chemical vapor deposition (MOCVD) process or molecular beam epitaxy (MBE) process.

The quantum dot QD-C may include a group II-VI semiconductor compound, a group I-II-VI semiconductor compound, a group II-IV-VI compound, a group I-II-IV-VI semiconductor compound, a group III-V semiconductor compound, a group III-VI semiconductor compound, a group I-III-VI semiconductor compound, a group IV-VI semiconductor compound, a group II-IV-V semiconductor compound, a group IV element or compound, or any combination thereof. In the specification, "Group" means a group of the IUPAC Periodic Table.

Examples of the II-VI group semiconductor compound may include binary compounds such as CdS, CdSe, CdTe, ZnS, ZnSe, ZnTe, ZnO, HgS, HgSe, HgTe, MgSe, and MgS, ternary compounds such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and MgZnS, quaternary compounds such as CdZnSeS, CdZnSeTe, CdZnSTe, CdHgSeS, CdHgSeTe, CdHgSTe, HgZnSeS, HgZnSeTe, and HgZnSTe, or any combination thereof.

The group II-VI semiconductor compound may further include a group I metal and/or a group IV element. The group I-II-VI semiconductor compound may be selected from CuZnS, and a group II-IV-VI compound may be selected from ZnSnS or the like. The group I-II-IV-VI compound may be selected from quaternary compounds selected from the group consisting of Cu₂ZnSnS₂, Cu₂ZnSnS₄, Cu₂ZnSnSe₄, Ag₂ZnSnS₂, and mixtures thereof.

Examples of the group III-V semiconductor compound may include binary compounds such as GaN, GaP, GaAs, GaSb, AlN, AlP, AlAs, AlSb, InN, InP, InAs, and InSb, ternary compounds such as GaNP, GaNAs, GaNSb, GaPAs, GaPSb, AlNP, AlNAs, AlNSb, AlPAs, AlPSb, InGaP, InNP, InAlP, InNAs, InNSb, InPAs, and InPSb, quaternary compounds such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb, or a combination thereof. The group III-V semiconductor compound may further include a group II element. Examples of the group III-V semiconductor compound further including the group II element may include InZnP, InGaZnP, InAlZnP, or the like.

Examples of the group III-VI semiconductor compound may include binary compounds such as GaS, Ga₂S₃, GaSe, Ga₂Se₃, GaTe, InS, InSe, In₂Se₃, and InTe, ternary compounds such as InGaS₃ and InGaSe₃, or any combination thereof.

Examples of the group I-III-VI semiconductor compound may include ternary compounds such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, and AgAlO₂, quaternary compounds such as AgInGaS₂ and AgInGaSe₂, or any combination thereof.

Examples of the group IV-VI semiconductor compound may include binary compounds such as SnS, SnSe, SnTe, PbS, PbSe, and PbTe, ternary compounds such as SnSeS, SnSeTe, SnSTe, PbSeS, PbSeTe, PbSTe, SnPbS, SnPbSe, and SnPbTe, quaternary compounds such as SnPbSSe, SnPbSeTe, and SnPbSTe, or any combination thereof.

Examples of the group II-IV-V semiconductor compound may be a ternary compound selected from the group consisting of ZnSnP, ZnSnP₂, ZnSnAs₂, ZnGeP₂, ZnGeAs₂, CdSnP₂, CdGeP₂, and mixtures thereof.

The group IV element or compound may include single element such as Si and Ge, binary compounds such as SiC and SiGe, or a combination thereof.

Elements included in a multi-element compound such as the binary compound, the ternary compound, and the quaternary compound may be present inside particles at a uniform concentration or a non-uniform concentration. That is, the chemical formula means the type (or kind) of elements included in the compound, and an element ratio in the compound may be different. For example, AgInGaS₂ may mean AgInₓGa₁₋ₓS₂ (x is a real number of 0 to 1).

The quantum dot QD-C may have a single structure in which concentrations of the elements included in the corresponding quantum dot QD-C are uniform (e.g., substantially uniform) or a core-shell dual structure. For example, a material included in the core and a material included in the shell may be different from each other.

The shell of the quantum dot QD-C may serve as a protective layer to maintain semiconductor characteristics by preventing or reducing chemical denaturation of the core and/or a charging layer for providing electrophoretic characteristics to the quantum dot QD-C. The shell may be a single layer or a multi-layer. The core-shell dual structure may have a concentration gradient in which the concentration of the element that is present in the shell decreases along a direction toward the core.

Examples of the shell of the quantum dot QD-C may include oxides of metals or nonmetals, semiconductor compounds, or combinations thereof. Examples of the oxides of the metals or nonmetals may include binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO, ternary compounds such as MgAl₂O₄, CoFe₂O₄, NiFe₂O₄, and CoMn₂O₄, or any combination thereof. Examples of the semiconductor compound may include, as described in the specification, the group III-VI semiconductor compound, the group II-VI semiconductor compound, the group III-V semiconductor compound, the group I-III-VI semiconductor compound, the group IV-VI semiconductor compound, or any combination thereof. For example, the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, and AlSb or any combination thereof.

Elements included in a multi-element compound such as the binary compound and the ternary compound may be present inside particles at a uniform concentration or a non-uniform concentration. For example, the chemical formula means the type (or kind) of elements included in the compound, and an element ratio in the compound may be different.

The quantum dot QD-C may have a full width of half maximum (FWHM) of a light emitting wavelength spectrum of about 45nm or less, for example, about 40 nm or less, or about 30 nm or less, and in this range, color purity and/or color reproducibility may be improved. Furthermore, the light emitted through the quantum dot QD-C may be emitted in all directions, and thus an optical viewing angle may be improved. In one or more embodiments, the shape of the quantum dot QD-C may specifically be in the form of a sphere, a pyramid, a multi-arm, a cubic nanoparticle, a nanotube, a nanowire, a nanofiber, a nanoplate, and/or the like.

An energy band gap may be adjusted by adjusting the size of the quantum dot QD-C or by adjusting an element ratio in the compound constituting the quantum dot QD-C, light having various wavelength bands may be obtained from the light emitting layer EML including the quantum dot QD-C. Thus, the light emitting elements ED, ED-a, ED-b, and ED-c that emit light having one or more suitable wavelengths may be implemented by using the quantum dot QD-C as described above (using quantum dots having different sizes and/or varying element ratios in quantum dot compounds). For example, in one or more embodiments, the size of the quantum dot QD-C and/or the element ratio in the compound constituting the quantum dot QD-C may be selected to emit red light, green light, and/or blue light. Furthermore, the quantum dots QD-C may be configured to emit white light obtained by combining light having one or more suitable colors.

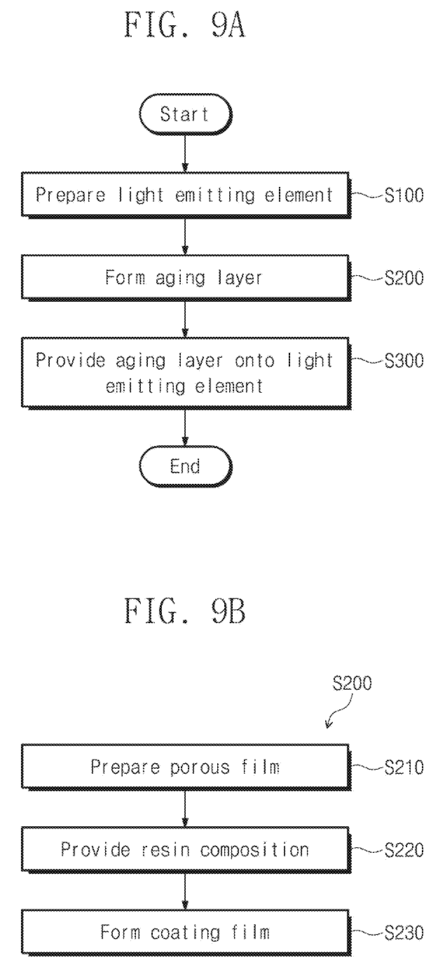

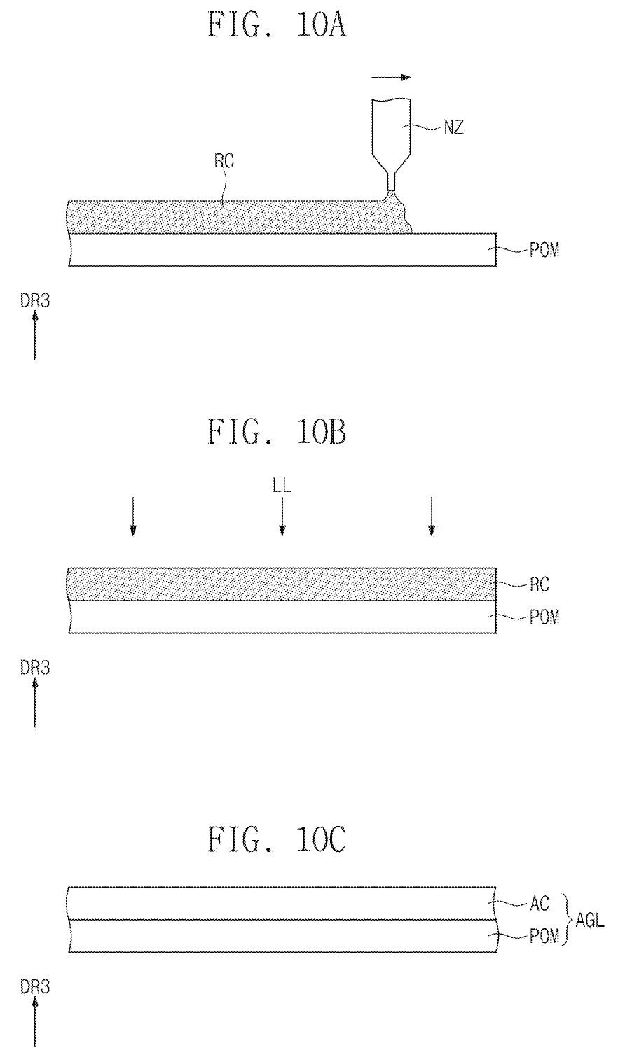

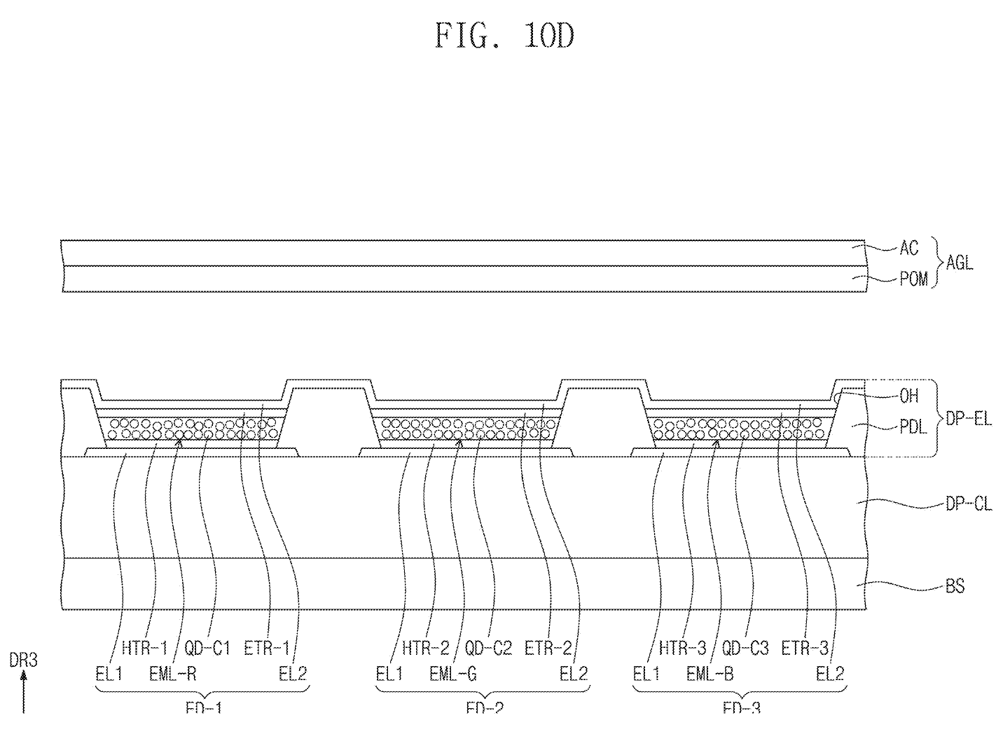

The electronic device according to one or more embodiments may be manufactured by the method of manufacturing an electronic device according to one or more embodiments. FIGS. 9A and 9B are flowcharts illustrating a method of manufacturing an electronic device according to one or more embodiments. FIGS. 10A-10D are schematic views illustrating operations of manufacturing an electronic device according to one or more embodiments. Hereinafter, in description of FIGS. 9A-10D, contents duplicated with the contents described with reference to FIGS. 1-8D will not be described again, and differences therebetween will be mainly described.

Referring to FIG. 9A, the method of manufacturing an electronic device according to one or more embodiments may include operation S100 of preparing a light emitting element including a light emitting layer including a quantum dot and an electron transport area including a metal oxide, operation S200 of forming an aging layer, and operation S300 of providing the aging layer onto the light emitting element. Referring to FIG. 9B, operation S200 of forming the aging layer may include operation S210 of preparing a porous film including a polymer, a ceramic, or a combination thereof, operation S220 of providing a resin composition including an organic acid onto the porous film, and operation S230 of forming a coating film by radiating light onto the resin composition.

FIGS. 10A-10D may be a method of manufacturing an electronic device including the aging layer AGL illustrated in FIG. 7. Referring to FIG. 10A, a resin composition RC may be provided on the porous film POM. The resin composition RC may be provided on the porous film POM through a nozzle NZ. The resin composition RC may be provided by an inkjet printing method and/or a dispensing method. In one or more embodiments, the liquid resin composition RC may be provided at a uniform amount (e.g. a substantially uniform amount) and/or at a uniform speed (e.g. a substantially uniform speed). FIG. 10A illustrates that the resin composition RC is provided through the nozzle NZ, but a device to provide the resin composition RC is not limited thereto.

The resin composition RC may include an organic acid. In one or more embodiments, the resin composition RC may further include a polymer matrix.

Referring to FIGS. 10B and 10C, light LL may be provided on the resin composition RC applied to the porous film POM at a set or certain thickness. The liquid resin composition RC may be cured by the light LL to form the coating film AC.

Referring to FIG. 10D, the aging layer AGL including the porous film POM and the coating film AC may be provided on surfaces of the light emitting elements ED-1, ED-2, and ED-3. The aging layer AGL may be attached to the light emitting elements ED-1, ED-2, and ED-3 through a lamination process. In one or more embodiments, the encapsulation layer TFE (see FIG. 5) may be further provided on the aging layer AGL.

The method of manufacturing an electronic device according to one or more embodiments, which includes operation of forming the aging layer, may exhibit excellent or suitable manufacturing efficiency. The method of manufacturing an electronic device according to the related art, which includes an operation of coating the encapsulation layer with an acidic solution, may be applied when a small-sized panel is manufactured. The method of manufacturing an electronic device according to one or more embodiments, which includes an operation of providing the aging layer on the light emitting element after operation of forming the aging layer, may be applied when a large panel is manufactured.

The electronic device according to one or more embodiments, which is manufactured by the method of manufacturing an electronic device according to one or more embodiments, may include the aging layer on the light emitting element. The aging layer may include the porous film including a polymer, a ceramic, or a combination thereof and the coating film including an organic acid, and thus may contribute to the light emitting element exhibiting high luminous efficiency and long lifetime characteristics. Accordingly, the electronic device according to one or more embodiments may exhibit excellent or suitable display quality and excellent or suitable reliability.

An electronic device according to one or more embodiments may include an aging layer on a light emitting element, the aging layer may include a porous film including a polymer, a ceramic, or a combination thereof and a coating film including an organic acid, and thus excellent or suitable display quality and excellent or suitable reliability may be achieved.

A method of manufacturing an electronic device according to one or more embodiments may include providing an aging layer onto a light emitting element after forming of the aging layer, thereby exhibiting excellent or suitable manufacturing efficiency.

Although the description has been made above with reference to one or more embodiments of the present disclosure, it is understood that the present disclosure should not be limited to these embodiments but one or more suitable changes and modifications can be made by those skilled in the art or those having ordinary knowledge in the art within the spirit and technical scope of the present disclosure described in the appended claims.

Thus, the technical scope of the present disclosure is not limited to the contents described in the detailed description of the specification, but should be determined by the appended claims, and equivalents thereof.

What is claimed is:

1. An electronic device comprising a display module configured to provide an image,
wherein the display module comprises a display element layer comprising a light emitting element and an aging layer on the light emitting element,
wherein the light emitting element comprises a first electrode, a second electrode on the first electrode, a light emitting layer between the first electrode and the second electrode comprising a quantum dot, and an electron transport area comprising a metal oxide between the first electrode and the second electrode, and
wherein the aging layer comprises:
a porous film comprising a polymer, a ceramic, or a combination thereof on the light emitting element; and
a coating film comprising an organic acid on the porous film.

2. The electronic device of claim 1, wherein a thickness of the porous film is in a range of 5μm to 100μm.

3. The electronic device of claim 1, wherein the polymer comprises polydimethylsiloxane, and
the ceramic comprises a silicon oxy carbide.

4. The electronic device of claim 1, wherein the coating film further comprises a polymer matrix.

5. The electronic device of claim 1, wherein the organic acid comprises a methacrylic acid, an acrylic acid, a citric acid, or a combination thereof.

6. The electronic device of claim 1, wherein the organic acid comprises a carboxyl group.

7. The electronic device of claim 1, wherein the aging layer is directly on the light emitting element.

8. The electronic device of claim 1, wherein the display module further comprises an encapsulation layer on the aging layer.

9. The electronic device of claim 1, wherein the metal oxide comprises SnO, SnO₂ CuGaO₂ Ga₂O₃ Cu₂O, SrCu₂O₂ SrTiO₃ CuAlO₂ Ta₂O₅ NiO, BaSnO₃ TiO₂ a compound represented by a following chemical formula M-1, or a combination thereof,
[Chemical formula M-1]
Zn_{(1-q)}Me_{q}O
wherein, in the Chemical formula M-1, q is 0 or more and 0.5 or less, and
wherein Me is Li, Be, Na, Mg, Al, K, Ca, Ti, V, Cr, Mn, Fe, Co, Ni, Cu, Ga, Ge, Rb, Sr, Zr, Nb, Mo, Ru, Pd, Ag, In, Sn(II), Sn(IV), Sb, or Ba.

10. The electronic device of claim 1, wherein the light emitting element further comprises a hole transport area, and
wherein one of the hole transport area and the electron transport area is between the first electrode and the light emitting layer, and the other one thereof is between the light emitting layer and the second electrode.

11. The electronic device of claim 1, further comprising:
a processor, a memory, a power module, or a combination thereof.

12. A method of manufacturing an electronic device, the method comprising:
preparing a light emitting element;
forming an aging layer; and
providing the aging layer onto the light emitting element,
wherein the forming of the aging layer includes:
preparing a porous film;
providing a resin composition comprising an organic acid onto the porous film; and
forming a coating film by radiating light to the resin composition,
wherein the light emitting element comprises a first electrode, a second electrode on the first electrode, a light emitting layer between the first electrode and the second electrode comprising a quantum dot, and an electron transport area comprising a metal oxide between the first electrode and the second electrode, and
wherein the porous film comprises a polymer, a ceramic, or a combination thereof.

13. The method of claim 12, further comprising:
providing an encapsulation layer onto the aging layer after the providing of the aging layer.

14. The method of claim 12, wherein the aging layer is coupled to the light emitting element in a lamination process.

15. The method of claim 12, wherein a thickness of the porous film is in a range of 5 μm to 100 μm.

16. The method of claim 12, wherein the polymer comprises polydimethylsiloxane, and
the ceramic comprises a silicon oxy carbide.

17. The method of claim 12, wherein the organic acid comprises a methacrylic acid, an acrylic acid, a citric acid, or a combination thereof.

18. The method of claim 12, wherein the resin composition further comprises a polymer matrix.

19. The method of claim 12, wherein the resin composition is provided by an inkjet printing method, a dispensing method, or a combination thereof.

20. The method of claim 12, wherein the metal oxide comprises SnO, SnO₂ CuGaO₂ Ga₂O₃ Cu₂O, SrCu₂O₂ SrTiO₃ CuAlO₂ Ta₂O₅ NiO, BaSnO₃ TiO₂ a compound represented by a following chemical formula M-1, or a combination thereof,
[Chemical formula M-1]
Zn_{(1-q)}Me_{q}O
wherein, in the chemical formula M-1, q is 0 or more and 0.5 or less, and
wherein Me is Li, Be, Na, Mg, Al, K, Ca, Ti, V, Cr, Mn, Fe, Co, Ni, Cu, Ga, Ge, Rb, Sr, Zr, Nb, Mo, Ru, Pd, Ag, In, Sn(II), Sn(IV), Sb, or Ba.
